(19) United States
(12) Patent Application Publication
(10) Pub. No.: US 2018/0358921 A1
(43) Pub. Date: Dec. 13, 2018

(54) SOLAR TRACKER

(71) Applicants: Mark Henderson, La Verne, CA (US); Adam Plesniak, Huntington beach, CA (US)

(72) Inventors: Mark Henderson, La Verne, CA (US); Adam Plesniak, Huntington beach, CA (US)

(21) Appl. No.: 15/997,668

(22) Filed: Jun. 4, 2018

Related U.S. Application Data
(60) Provisional application No. 62/517,529, filed on Jun. 9, 2017.

(51) Int. Cl. H02S 20/32; H01L 31/042; G05D 3/10

(52) U.S. Cl. CPC H02S 20/32; F24S 30/452; G05D 3/105; H01L 31/042

(57) ABSTRACT

A single axis tracker system including at least one photovoltaic panel, a mounting structure, and a tracker control system. The tracker control system being attached to the at least one photovoltaic panel and to the mounting structure so as to apply torque to the at least one photovoltaic panel to rotate the at least one photovoltaic panel into an allowable orientation. A wind tracking device is coupled to the single axis tracker system and connected to the tracker control system. The wind tracking device determines current wind speed and direction information and couples the wind speed and direction information to an algorithm in the tracker control system. The algorithm uses the wind speed and direction information to calculate an allowable photovoltaic panel orientation for the current conditions.

### CROSS-REFERENCE TO RELATED APPLICATION

This application claims the benefit of U.S. Provisional Patent Application No. 62/517,529, filed 9 Jun. 2017.

### FIELD OF THE INVENTION

This invention relates to solar trackers and more specifically to single axis solar trackers.

### BACKGROUND OF THE INVENTION

A single axis solar tracker is a device which holds PV panels (panels of photovoltaic sensors) and rotates the panels from east to west throughout the day to increase the output of electrical energy from the panels and reduce cosine loss.

Previous single axis solar trackers are made to a level of structural rigidity to survive high wind loading in virtually all orientations throughout a day of tracking (i.e. from pointing east in the morning to pointing west in the evening). It will be understood by those of skill in the art that wind loads on a panel will differ depending upon the orientation of the panel. In these prior art panels, the turning torque must be sufficient to overcome a maximum wind force (stow wind speed) on the panel in virtually all orientations. Most prior art single axis solar trackers are designed to stow at a wind speed of about 40 mph. Wind stow is defined as the orientation where wind loading on the tracker is minimized. This structural rigidity to survive high wind loading in prior art trackers greatly increases the cost of single axis solar trackers over fixed tilt racking systems.

It would be highly advantageous, therefore, to remedy this and other deficiencies inherent in the prior art.

Accordingly, it is an object of the present invention to provide a new and improved single axis solar tracker.

It is another object of the present invention to provide a new and improved single axis solar tracker that is inexpensive, and easy and efficient to operate.

It is another object of the present invention to provide a new and improved single axis solar tracker structure that is lower cost than a fixed tilt solar mounting system structure.

It is another object of the present invention to provide a new and improved single axis solar tracker structure that includes a stow mode for winds above an operational limit and which is operated in a fully sun tracking mode under fair weather conditions and a dynamic wind stow mode with wind speeds near the operational limit.

### SUMMARY OF THE INVENTION

Briefly to achieve the desired objects and advantages of the instant invention a single axis tracker system is provided including at least one photovoltaic panel, a mounting structure, and a tracker control system. The tracker control system is attached to the at least one photovoltaic panel and to the mounting structure so as to apply torque to the at least one photovoltaic panel to rotate the at least one photovoltaic panel into an allowable orientation. A wind tracking device is coupled to the single axis tracker system and connected to the tracker control system. The wind tracking device determines current wind speed and direction information and couples the wind speed and direction information to an algorithm in the tracker control system. The algorithm uses the wind speed and direction information to calculate an allowable photovoltaic panel orientation.

The desired objects and advantages of the instant invention are further achieved in a preferred embodiment of a single axis tracker system including at least one photovoltaic panel, a mounting structure, a tracker control system attached to the at least one photovoltaic panel and to the mounting structure. The tracker control system applies torque to the at least one photovoltaic panel to rotate the at least one photovoltaic panel into an allowable orientation. The system further includes a wind tracking device coupled to the single axis tracker system and connected to the tracker control system, the wind tracking device determining current wind speed and direction information and coupling the wind speed and direction information to an algorithm in the tracker control system. The algorithm uses the wind speed and direction information to calculate an allowable photovoltaic panel orientation. The at least one photovoltaic panel and attached tracker control system includes a stow orientation for the at least one photovoltaic panel, the tracker control system rotating the at least one photovoltaic panel into the stow orientation when the wind tracking device determines current wind speed in excess of an operational limit. The at least one photovoltaic panel and attached tracker control system operating in a fully sun tracking mode under fair weather conditions, that is at wind speeds less than approximately 3 miles per hour below the operational limit. The at least one photovoltaic panel and attached tracker control system operating in a dynamic wind stow mode with wind speeds within a range of approximately 3 mph below the operational limit. In the dynamic wind stow mode the tracker control system orients the at least one photovoltaic panel into a minimum acceptable load condition, to optimize energy generation without risking structural integrity.

The desired objects and advantages of the instant invention are further achieved in a preferred method of controlling a single axis tracker system to allow a structural design presenting minimal wind loading for lower structural requirements and lighter weight overall structure than existing single axis solar trackers. The method includes the step of providing at least one photovoltaic panel, a mounting structure, and a tracker control system attached to the at least one photovoltaic panel and to the mounting structure, the tracker control system being coupled to apply torque to the at least one photovoltaic panel to rotate the at least one photovoltaic panel into allowable orientations. The method further includes the steps of providing a wind tracking device coupled to the single axis tracker system, and connecting the wind tracking device to the tracker control system, the wind tracking device determining current wind speed and direction information and coupling the wind speed and direction information to an algorithm in the tracker control system, the algorithm using the wind speed and direction information to calculate allowable photovoltaic panel orientations. The at least one photovoltaic panel and attached tracker control system including a stow orientation for the at least one photovoltaic panel, the tracker control system rotating the at least one photovoltaic panel into the stow orientation when the wind tracking device determines current wind speed in excess of an operational limit. The method further includes the steps of operating the at least one photovoltaic panel and attached tracker control system in a fully sun tracking mode under fair weather conditions, that is at wind speeds less than approximately 3 miles per hour below the operational limit and operating the at least one photovoltaic panel and attached tracker control system in a dynamic wind stow mode with wind speeds within a range of approximately 3 mph below the operational limit, in the dynamic wind stow mode the tracker control system orients the at least one photovoltaic panel into a minimum acceptable load condition, to optimize energy generation without risking structural integrity.

### BRIEF DESCRIPTION OF THE DRAWINGS

Specific objects and advantages of the invention will become readily apparent to those skilled in the art from the following detailed description of a preferred embodiment thereof, taken in conjunction with the drawings in which:

FIG. 1 is a graphical presentation illustrating solar radiation versus wind speed;

FIG. 2 illustrates single axis solar panel orientation throughout a day during fair weather;

FIG. 3 illustrates single axis solar panel orientation throughout a day with wind speeds close to the operational limit; and

FIG. 4 illustrates single axis solar panel orientation throughout a day during high wind speed.

### DETAILED DESCRIPTION OF THE DRAWINGS

In general, the present invention is an improved approach to single axis solar panel trackers. The presently disclosed novel single axis solar tracker is intended to be lower cost than a fixed tilt solar mounting system and is designed to stow, or move the panels to a lower drag position, at lower wind induced loads. Stowing or moving to a lower drag position at lower wind induced loads allows for a lighter weight overall structure than existing single axis solar trackers. Also, the presently disclosed novel structure requires less material than fixed tilt systems, as fixed tilt systems are designed for maximum worst case wind loading (90-110 mph in most areas) due to their fixed drag profile, determined by the tilt and relative orientation of the PV panels. In summary, the presently disclosed novel single axis solar tracker has a structural design and control code that dynamically wind stows at low wind loads (e.g. 12-15 mph) and only fully tracks the sun in “fair weather” (e.g. less than 12 mph). In all other conditions (e.g. winds greater than 15 mph) the present tracker stows to present minimal wind loading to allow for lower structural strength requirements.

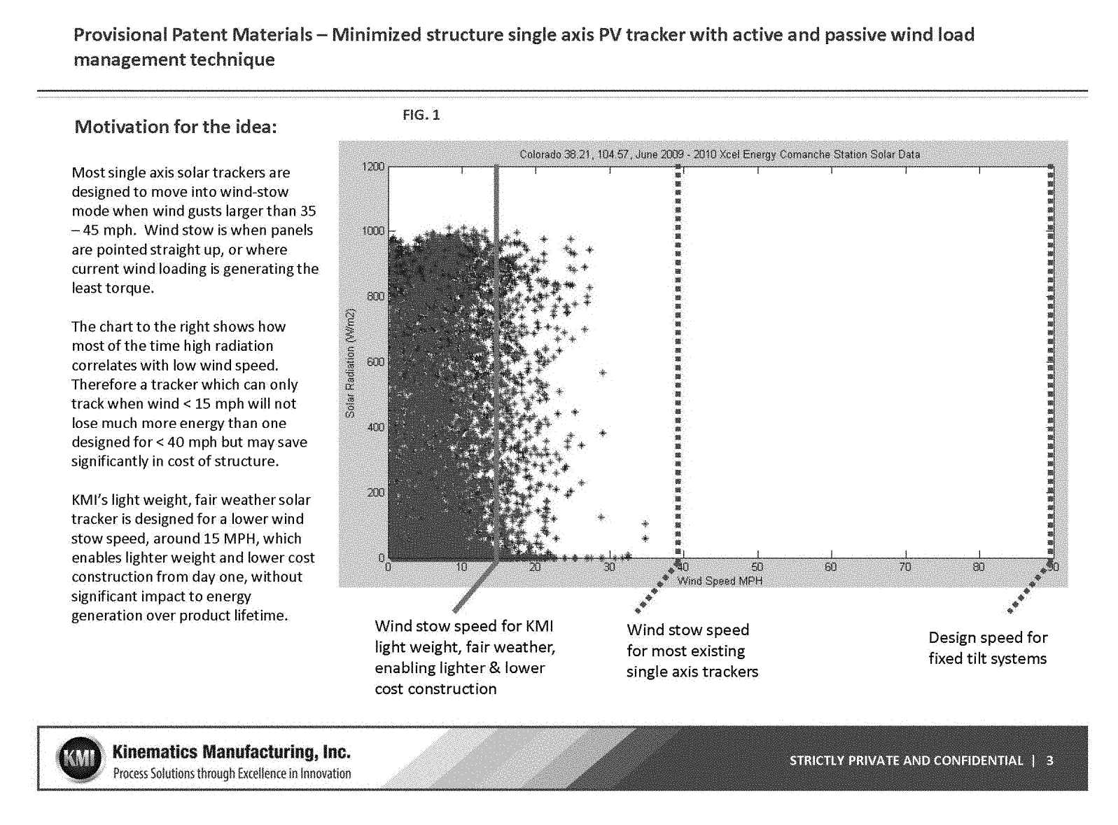

Turning to FIG. 1, solar radiation versus wind speed is illustrated to show that most of the time high radiation correlates with low wind speed. Therefore, a tracker which only tracks during low wind speeds, preferably less than approximately 15 mph, will not lose much more energy than a solar tracker designed for tracking at up to 40 mph wind speeds. However, the structural difference will significantly lower the cost.

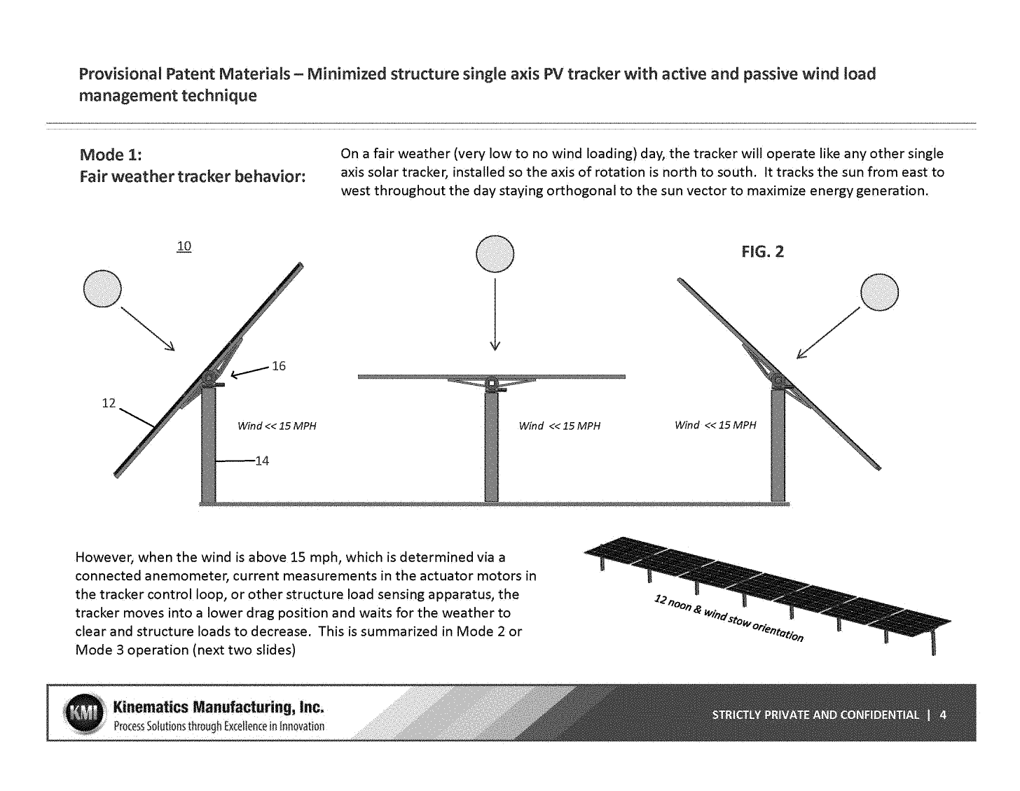

Referring now to FIG. 2, a single axis solar tracker 10 orientation throughout a day during fair weather (i.e. wind speed less than 12 mph) is illustrated. Single axis solar tracker 10 includes one or more PV panels 12 and mounting structure 14. A tracker control system 16 is attached to PV panels 12 and mounting structure 14 and provides the necessary torque for rotating PV panel 12 into the required orientation. Wind speed and direction is determined by a wind tracking device. In the preferred embodment, the wind tracking device is an anemometer, illustrated in this specific embodiment as a component of or connected adjacent tracker control system 16. The connected anemometer positioned adjacent tracker 10 (generally a single device can service a field of solar trackers 10) provides current measurements to a tracker control loop including actuator motors, in tracker control system 16. While an anemometer is preferred, it will be understood that other wind tracking devices can be employed to determine present and future wind speed and direction. Wind tracking devices used can include direct measuring devices such as an anemometer, or data collection devices which obtain wind data from other sources such as the National Weather Bureau, local sources and the like. Thus, localized wind data may not come from a physical measuring device, but from a data steam. For example, a network of private anemometers across the US can be networked to cell phone towers or satellites. Access to this network can provide a real-time data stream or even forward looking (say 5 minutes ahead) data stream. This data is collected (received) by the wind tracking device and used to decide how to orient the trackers at any given time. In most instances and operating areas, solar tracker 10 is installed by mounting structure 14 with the axis of rotation oriented approximately north-south (varies according to the latitude of position). Further, as illustrated, solar panel 12 is oriented by rotation about the rotary axis toward the sun, from morning at the left to evening at the right.

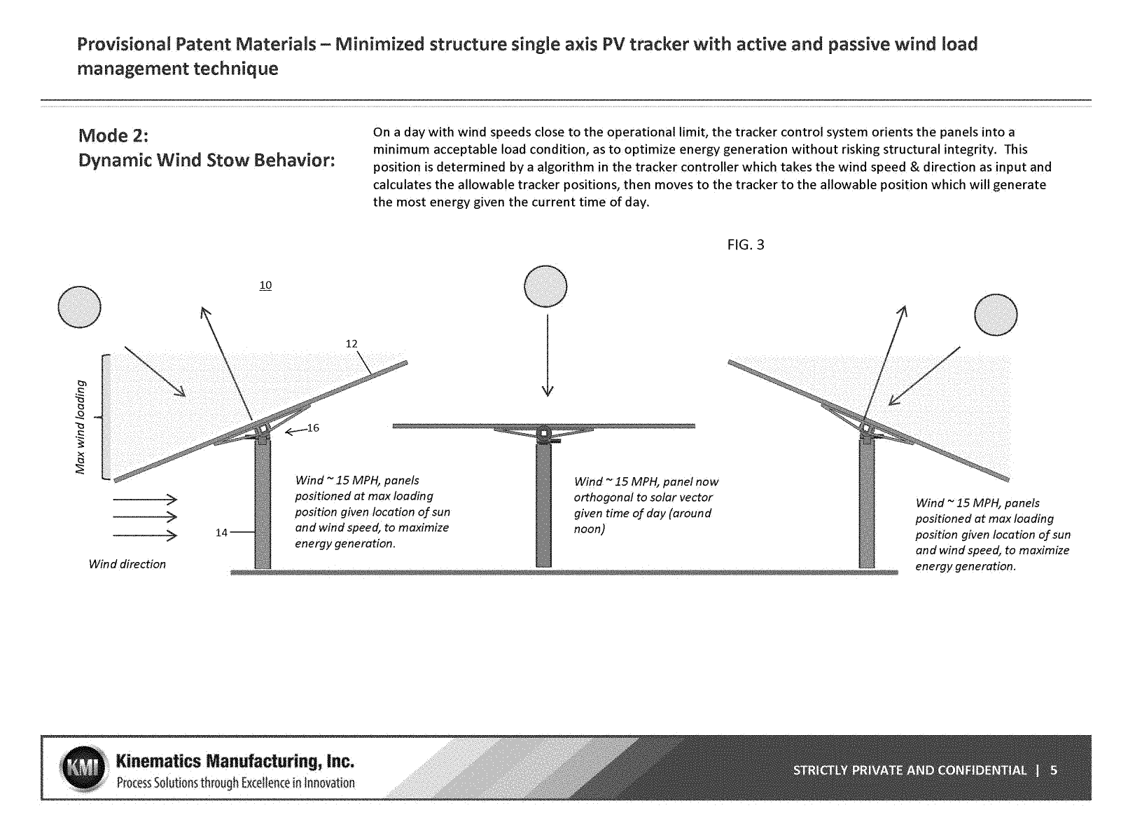

Dynamic wind stow mode or operation of solar tracker 10 is illustrated further in FIG. 3. On a day with wind speeds close to the operational limit (e.g. 12-15 mph or approximately 15 mph), tracker control system 16 orients PV panel 12 into a minimum acceptable load condition, to optimize energy generation without risking structural integrity. That is, PV panel 12 is oriented into a position in which the wind load is less than a wind load that might cause structural damage. This position is determined by an algorithm in tracker control system 16 which takes the wind speed and direction as inputs and calculates the allowable tracker positions. It should be understood that forces on a PV panel under various wind speeds and directions can easily be measured and or calculated or estimated from testing/investigation of the design (i.e. wind tunnel testing and analysis) so that the tracker algorithm is relatively straightforward. Tracker control system 16 then moves PV panel 12 to the “allowable position”. That is a position that will generate the most energy given the current time of day with an allowable wind force on the structure. For example, it can be seen by comparing the positions of FIG. 2 to the windless positions of FIG. 2 that the positions of PV panel 12 start and end in a flatter or more horizontal orientation which produce less wind force while still generating the most energy.

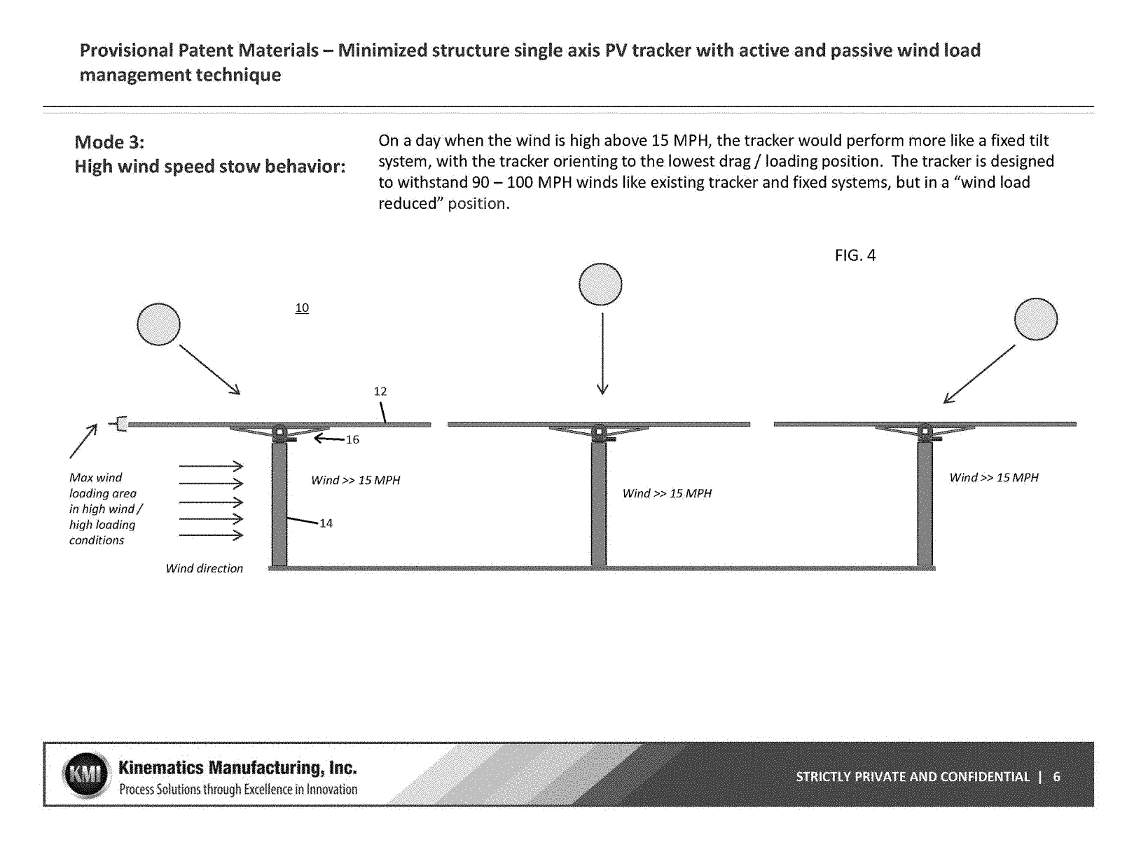

High wind speed stow operation of solar tracker 10 is illustrated further in FIG. 4. On a day when the wind speed is high, in this preferred example higher than 15 mph, solar tracker 10 is oriented by tracker control system 16 to the lowest drag/loading position. As understood by those of skill in the art, the lowest drag/loading position may be horizontal as illustrated in FIG. 4 as the position of PV panel 12 throughout the day (i.e. as long as the wind speed is high). In this orientation solar tracker 10 is designed to withstand 90-120 mph winds. It should be noted that even in the stow position some energy is still generated.

In summary, a single axis tracker system and method of operation is disclosed. The tracker system includes at least one photovoltaic panel, a mounting structure, and a tracker control system. The tracker control system is attached to the photovoltaic panel and to the mounting structure to apply torque to the photovoltaic panel to rotate it into an allowable orientation. A wind tracking device, such as an anemometer is connected to the tracker control system for determining current wind speed and direction information. Allowable photovoltaic panel orientations of the at least one photovoltaic panel and attached tracker control system include operating in a fully sun tracking mode under fair weather conditions, operating in a dynamic wind stow mode with wind speeds within a range of approximately 3 mph below the operational limit, and a stow orientation for wind speeds in excess of an operational limit. In a preferred embodiment the operational limit is approximately 15 mph but could vary by up to 5 mph for specific areas and applications.

Thus, the present invention discloses and provides a new and improved single axis solar tracker that is designed to operate like other single axis solar trackers in fair weather conditions but moves into positions of minimal acceptable load conditions under wind speeds close to the operational limit and moves into the stow position when the wind is above the operational limit. The new and improved single axis solar tracker is inexpensive, and easy and efficient to operate and is lower cost than a fixed tilt solar mounting system without a large detriment to energy production over current single axis solar trackers. Further, because most of the time high radiation correlates with low wind speed the present solar tracker will not lose much more energy than a solar tracker designed for up to 40 mph wind speeds but the structural difference will significantly lower the cost.

Various changes and modifications to the embodiments herein chosen for purposes of illustration will readily occur to those skilled in the art. To the extent that such modifications and variations do not depart from the spirit of the invention, they are intended to be included within the scope thereof which is assessed only by a fair interpretation of the following claims.

Having fully described the invention in such clear and concise terms as to enable those skilled in the art to understand and practice the same, the invention claimed is:

1. A single axis tracker system comprising:
at least one photovoltaic panel;
a mounting structure;
a tracker control system attached to the at least one photovoltaic panel and to the mounting structure, the tracker control system applying torque to the at least one photovoltaic panel to rotate the at least one photovoltaic panel into an allowable orientation; and
a wind tracking device associated with the single axis tracker system and connected to the tracker control system, the wind tracking device determining current wind speed and direction information and coupling the wind speed and direction information to an algorithm in the tracker control system, the algorithm using the wind speed and direction information to calculate an allowable photovoltaic panel orientation.

2. The single axis tracker system as claimed in claim 1 wherein allowable photovoltaic panel orientations of the at least one photovoltaic panel and attached tracker control system include a stow orientation for the at least one photovoltaic panel, the tracker control system rotating the at least one photovoltaic panel into the stow orientation when the wind tracking device determines current wind speed in excess of an operational limit.

3. The single axis tracker system as claimed in claim 2 wherein the operational limit is approximately 15 miles per hour.

4. The single axis tracker system as claimed in claim 2 wherein allowable photovoltaic panel orientations of the at least one photovoltaic panel and attached tracker control system include operating in a fully sun tracking mode under fair weather conditions, that is at wind speeds less than approximately 3 miles per hour below the operational limit.

5. The single axis tracker system as claimed in claim 2 wherein allowable photovoltaic panel orientations of the at least one photovoltaic panel and attached tracker control system include operating in a dynamic wind stow mode with wind speeds within a range of approximately 3 mph below the operational limit.

6. The single axis tracker system as claimed in claim 5 where, in the dynamic wind stow mode, the tracker control system orients the at least one PV panel into a minimum acceptable load condition, to optimize energy generation without risking structural integrity.

7. The single axis tracker system as claimed in claim 1 wherein the at least one photovoltaic panel, the mounting structure, and the tracker control system include a structural design presenting minimal wind loading to allow for lower structural requirements and lighter weight overall structure than existing single axis solar trackers.

8. A single axis tracker system comprising:
at least one photovoltaic panel;
a mounting structure;
a tracker control system attached to the at least one photovoltaic panel and to the mounting structure, the tracker control system applying torque to the at least one photovoltaic panel to rotate the at least one photovoltaic panel into an allowable orientation;
a wind tracking device coupled to the single axis tracker system and connected to the tracker control system, the wind tracking device determining current wind speed and direction information and coupling the wind speed and direction information to an algorithm in the tracker control system, the algorithm using the wind speed and direction information to calculate the allowable photovoltaic panel orientation;
allowable photovoltaic panel orientations of the at least one photovoltaic panel and attached tracker control system include a stow orientation for the at least one photovoltaic panel, the tracker control system rotating the at least one photovoltaic panel into the stow orientation when the wind tracking device determines current wind speed in excess of an operational limit;
allowable photovoltaic panel orientations of the at least one photovoltaic panel and attached tracker control system include operating in a fully sun tracking mode under fair weather conditions, that is at wind speeds less than approximately 3 miles per hour below the operational limit; and
allowable photovoltaic panel orientations of the at least one photovoltaic panel and attached tracker control system include operating in a dynamic wind stow mode with wind speeds within a range of approximately 3 mph below the operational limit, in the dynamic wind stow mode the tracker control system orients the at least one photovoltaic panel into a minimum acceptable load condition, to optimize energy generation without risking structural integrity.

9. The single axis tracker system as claimed in claim 8 wherein the operational limit is approximately 15 miles per hour.

10. The single axis tracker system as claimed in claim 8 wherein the at least one photovoltaic panel, the mounting structure, and the tracker control system include a structural design presenting minimal wind loading to allow for lower structural requirements and lighter weight overall structure than existing single axis solar trackers.

11. A method of controlling a single axis tracker system to allow a structural design presenting minimal wind loading for lower structural requirements and lighter weight overall structure than existing single axis solar trackers, the method comprising the steps of:
providing at least one photovoltaic panel, a mounting structure, and a tracker control system attached to the at least one photovoltaic panel and to the mounting structure, the tracker control system being coupled to apply torque to the at least one photovoltaic panel to rotate the at least one photovoltaic panel into allowable orientations;
providing a wind tracking device, coupling the wind tracking device to the single axis tracker system, and connecting the wind tracking device to the tracker control system, the wind tracking device determining current wind speed and direction information and coupling the wind speed and direction information to an algorithm in the tracker control system, the algorithm using the wind speed and direction information to calculate allowable photovoltaic panel orientations;
allowable photovoltaic panel orientations of the at least one photovoltaic panel and attached tracker control system include a stow orientation for the at least one photovoltaic panel, the tracker control system rotating the at least one photovoltaic panel into the stow orientation when the wind tracking device determines current wind speed in excess of an operational limit; and
allowable photovoltaic panel orientations include operating the at least one photovoltaic panel and attached tracker control system in a fully sun tracking mode under fair weather conditions, that is at wind speeds less than the operational limit.

12. The method as claimed in claim 11 wherein the allowable photovoltaic panel orientations further include:
operating the at least one photovoltaic panel and attached tracker control system in a fully sun tracking mode under fair weather conditions, that is at wind speeds less than approximately 3 miles per hour below the operational limit; and
operating the at least one photovoltaic panel and attached tracker control system in a dynamic wind stow mode with wind speeds within a range of approximately 3 mph below the operational limit, in the dynamic wind stow mode the tracker control system orients the at least one photovoltaic panel into a minimum acceptable load condition, to optimize energy generation without risking structural integrity.

13. The method as claimed in claim 11 including in addition a step of designing the single axis tracker system for an operational limit of approximately 15 miles per hour.
